(19) United States
(12) Patent Application Publication
(10) Pub. No.: US 2004/0189418 A1
(43) Pub. Date: Sep. 30, 2004

(54) Method and structure for implementing enhanced differential signal trace routing

(75) Inventors: Gerald Keith Bartley, Rochester, MN (US); Paul Eric Dahlen, Rochester, MN (US); Philip Raymond Germann, Rochester, MN (US); Andrew B. Maki, Rochester, MN (US); Mark Owen Maxson, Mantorville, MN (US)

Correspondence Address: Robert R. Williams, IBM Corporation - Dept. 917, 3605 Highway 52 North, Rochester, MN, 55901, US

(73) Assignee: INTERNATIONAL BUSINESS MACHINES CORPORATION, Armonk, NY

(21) Appl. No.: 10/401,257

(22) Filed: Mar. 27, 2003

(51) Int. Cl. H05K 7/02; H01P 3/02

(52) U.S. Cl. 333/4; 361/777

(57) ABSTRACT

A method and structure are provided for implementing enhanced differential signal trace routing in a printed circuit board. The structure includes a differential signal trace pair and a differential pair via arrangement including a pair of vias. The pair of vias is coupled to the differential signal trace pair for routing the differential signal trace pair between first and second layers of the PCB. The vias are laterally offset by a predefined spacing sharing overlapping clearance holes and are diagonally oriented to allow minimal separation of the differential signal trace pair and matched signal trace lengths of the differential signal trace pair.

### FIELD OF THE INVENTION

The present invention relates generally to the arrangement of printed circuit boards, and more particularly, relates to a method and structure for implementing enhanced differential signal trace routing in a printed circuit board (PCB).

### DESCRIPTION OF THE RELATED ART

As used in the present specification and claims, the term printed circuit board or PCB means a substrate or multiple layers (multi-layer) of substrates used to electrically attach electrical components and should be understood to generally include circuit cards, printed circuit cards, printed wiring cards, and printed wiring boards.

Current and future high performance computer systems and server systems rely on both large-scale packaging of multiple high density interconnect modules and printed circuit boards. High signal speed integrated circuit devices are being fabricated in increasingly smaller sizes and requiring increasing numbers of connector pins or other connection interface structures within a spatial footprint. An increasing number of printed circuit board signal traces are required.

Particularly with the increased signal speed of integrated circuit devices, it is quite difficult to design a printed circuit board that provides required signal integrity. A significant signal integrity problem results from the conventional arrangement of PCB differential signal trace pairs.

FIG. 1 illustrates a conventional differential signal trace via construct for differential signal trace pair routing in printed circuit board in a plan view not to scale with signal traces on a lower signal plane shown in dotted line. As shown in FIG. 1, a differential signal trace pair is routed on an upper first signal layer shown in solid line. Differential signal trace pairs typically are routed between printed circuit board layers by parallel spaced-apart conductive through-holes or vias. Conventional differential signal trace pair vias are, for example, 8-15 mil vias. Differential signal trace pairs typically are for example, 2-5 mil traces spaced-apart by 3-8 mil spaces.

Typically the differential signal trace pair vias are oriented on 40-50 mil grid with each via including a separate or individual power plane clearance hole as shown in FIG. 1. In order to change routing planes, the differential signal trace pair must be separated substantially greater than the normal 3-8 mil spacing to accommodate the larger 40-50 mil pitch of a pair of adjacent differential signal trace pair vias. Following the plane change, the differential signal pair exits the differential signal trace pair vias similarly substantially separated such as shown on a lower signal layer illustrated in dotted line.

The separation of the differential signal trace pairs that occurs at the via pair interface adversely affects the fidelity of the transmitted signal. In addition to the characteristic impedance discontinuity in the transmission path due to the separation of the differential pairs and the electromagnetic fields disruption, differential skew is incurred as a result of a path length difference between the phases of the differential pair.

A need exists for an improved mechanism to provide differential signal trace routing in a printed circuit board that is effective and simple to implement and that does not require expensive processing and fabrication techniques.

### SUMMARY OF THE INVENTION

A principal object of the present invention is to provide a method and structure for implementing enhanced differential signal trace routing in a printed circuit board (PCB). Other important objects of the present invention are to provide such method and structure for implementing enhanced differential signal trace routing substantially without negative effect and that overcome some of the disadvantages of prior art arrangements.

In brief, a method and structure are provided for implementing enhanced differential signal trace routing in a printed circuit board. The structure includes a differential signal trace pair and a differential pair via arrangement including a pair of vias. The pair of vias is coupled to the differential signal trace pair for routing the differential signal trace pair between first and second layers of the PCB. The vias are laterally offset by a predefined spacing and are diagonally oriented to allow minimal separation of the differential signal trace pair.

In accordance with features of the invention, each via of the pair of vias includes a power plane clearance hole and a portion of the power plane clearance holes overlap. The differential pair via arrangement with the laterally offset and diagonally oriented vias allows matched signal trace lengths of the differential signal trace pair. The vias are diagonally oriented or rotated 45 degrees with respect to each other.

### BRIEF DESCRIPTION OF THE DRAWINGS

The present invention together with the above and other objects and advantages may best be understood from the following detailed description of the preferred embodiments of the invention illustrated in the drawings, wherein:

FIG. 1 is a plan view not to scale illustrating a conventional printed circuit board via arrangement for differential signal trace routing in the printed circuit board with signal traces on a lower signal plane shown in dotted line; and

FIG. 2 is plan view not to scale illustrating a printed circuit board (PCB) via arrangement for differential signal trace routing in the printed circuit board with signal traces on a lower signal plane shown in dotted line in accordance with the preferred embodiment.

### DETAILED DESCRIPTION OF THE PREFERRED EMBODIMENTS

In accordance with features of the preferred embodiment, as new card/board technology drives signal trace geometries smaller, coupled with increased signaling frequencies, alternative signal via constructs and orientation techniques are provided to both optimize signal trace routing and achieve acceptable signal integrity.

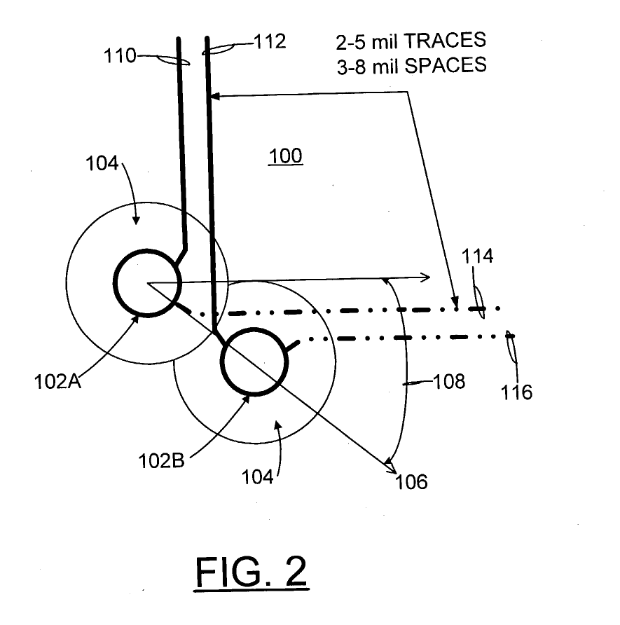

Having reference now to the drawings, in FIG. 2, there is shown a printed circuit board (PCB) differential pair via arrangement or construct for implementing differential signal trace pair routing generally designated by the reference character 100 in accordance with the preferred embodiment. The differential pair via arrangement 100 includes a pair of vias 102A, 102B including a pair of overlapping clearance holes 104, as shown.

In accordance with features of the preferred embodiment, the differential pair via arrangement 100 including a diagonal orientation of the pair of vias 102A, 102B is provided to allow for enhanced wiring density and improved electrical properties relative to high speed differential signaling in printed circuit boards.

In accordance with features of the preferred embodiment, the pair of vias 102A, 102B share the common power plane overlapping clearance holes 104 and are laterally offset and oriented diagonally relative to each other as indicated along a line 106 to create the differential pair via arrangement 100.

The pair of vias 102A, 102B are laterally offset or spaced apart by at least a minimum pitch defined by the external land diameter of the vias 102A, 102B and a minimum conductor-to-conductor spacing requirement for a particular differential signal trace pair.

As shown in FIG. 2, the diagonal orientation of the via pair includes the vias 102A, 102B rotated by a 45 degree angle with respect to each other as indicated by an arrow 108.

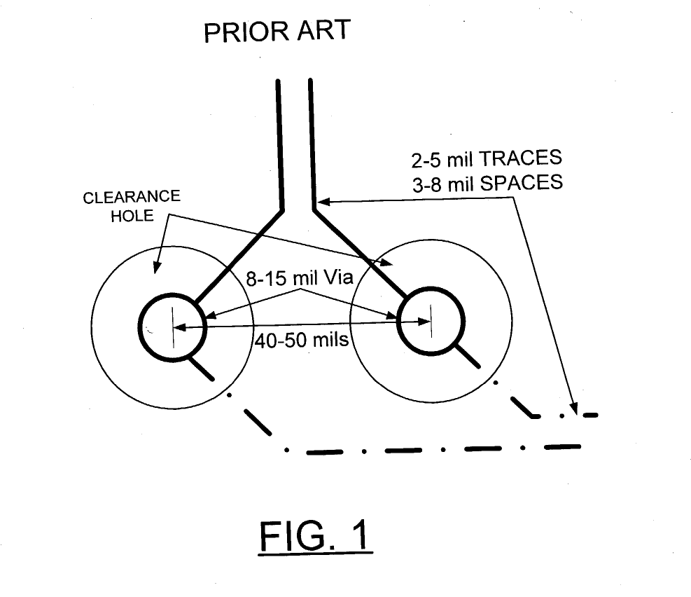

By vias 102A, 102B being laterally offset by a predefined spacing and sharing the overlapping or common clearance holes 104 and being located diagonally or rotated at a 45 degree angle, an upper plane differential signal trace pair 110,112 and a lower plane differential signal trace pair 114,116 can be routed directly in and out of this dual via construct 100 without separating the differential pair signal traces, as required in the conventional arrangement of FIG. 1.

In accordance with features of the preferred embodiment, the differential pair via construct 100 allows for minimum wire separation and matched signal trace lengths at any exit angle of the differential signal trace pair 110, 112 and 114,116. Vias 102A, 102B are, for example, 8-15 mil vias, the same as conventional differential signal trace pair vias. The upper plane differential signal trace pair 110, 112 and the lower plane differential signal trace pair 114, 116 are, for example, 2-5 mil traces spaced apart by 3-8 mil spaces; the same as conventional differential signal trace pairs, however without the required additional separation of the conventional differential pair signal traces at the via pair interface.

While the present invention has been described with reference to the details of the embodiments of the invention shown in the drawing, these details are not intended to limit the scope of the invention as claimed in the appended claims.

What is claimed is:

1. A structure for implementing enhanced differential signal trace routing in a printed circuit board (PCB) comprising:
a differential signal trace pair;
a differential pair via arrangement including a pair of vias; said pair of vias coupled to said differential signal trace pair for routing said differential signal trace pair between first and second layers of the PCB;
said vias being laterally offset by a predefined spacing and being diagonally oriented to allow minimal separation of said differential signal trace pair.

2. A structure for implementing enhanced differential signal trace routing as recited in claim 1 wherein said pair of vias are laterally offset by said predefined spacing, and said predefined spacing is defined by an external land diameter of said pair of vias and a predefined minimum spacing between said differential signal trace pair.

3. A structure for implementing enhanced differential signal trace routing as recited in claim 1 wherein each via of said pair of vias includes a clearance hole and wherein a portion of said clearance holes overlap.

4. A structure for implementing enhanced differential signal trace routing as recited in claim 1 wherein said pair of vias are diagonally oriented at a predefined angle.

5. A structure for implementing enhanced differential signal trace routing as recited in claim 4 wherein said predefined angle is 45 degrees.

6. A structure for implementing enhanced differential signal trace routing as recited in claim 1 wherein said differential pair via arrangement are laterally offset by said predefined spacing to enable matched signal trace lengths of said differential signal trace pair.

7. A method for implementing enhanced differential signal trace routing in a printed circuit board (PCB) comprising the steps of:
disposing a differential signal trace pair on a first layer of the PCB;
providing first and second vias in the PCB for routing said differential signal trace pair to a second layer of the PCB; and
providing said first and second vias laterally spaced apart by a predefined offset and diagonally oriented at a predefined angle.

8. A method for implementing enhanced differential signal trace routing as recited in claim 7 wherein the step of providing said first and second vias laterally spaced-apart by a predefined offset and diagonally oriented at a predefined angle includes the step of defining said predefined offset based upon an external land diameter of said first and second vias.

9. A method for implementing enhanced differential signal trace routing as recited in claim 7 wherein the step of providing said first and second vias laterally spaced-apart by a predefined offset and diagonally oriented at a predefined angle includes the step of defining said predefined offset based upon a predefined minimum spacing between said differential signal trace pair.

10. A method for implementing enhanced differential signal trace routing as recited in claim 7 wherein the step of providing said first and second vias laterally spaced-apart by a predefined offset and diagonally oriented at a predefined angle includes the step of providing said first and second vias diagonally oriented at a 45 degree angle.

11. A differential pair via arrangement for implementing enhanced differential signal trace routing in a printed circuit board (PCB) comprising:
a differential signal trace pair;
a pair of vias; said pair of vias coupled to said differential signal trace pair for routing said differential signal trace pair between first and second layers of the PCB; and
said vias being laterally offset by a predefined spacing and being diagonally oriented to allow minimal separation of said differential signal trace pair and matched signal trace lengths of said differential signal trace pair.

12. A differential pair via arrangement as recited in claim 11 wherein said vias are laterally offset by said predefined spacing, and said predefined spacing is defined by an external land diameter of said pair of vias and a predefined minimum spacing between said differential signal trace pair.

13. A differential pair via arrangement as recited in claim 11 wherein said vias are diagonally oriented at a predefined angle of 45 degrees.

14. A differential pair via arrangement as recited in claim 11 wherein each via of said pair of vias includes a clearance hole and wherein a portion of said clearance holes overlap.
